(19) United States
(12) Patent Application Publication
(10) Pub. No.: US 2014/0374891 A1
(43) Pub. Date: Dec. 25, 2014

(54) SEMICONDUCTOR DEVICE WITH HEAT SPREADER AND THERMAL SHEET

(71) Applicants: Boon Yew Low, Petaling Jaya (MY); Burton J. Carpenter, Austin, TX (US); Navas Khan Oratti Kalandar, Petaling Jaya (MY)

(72) Inventors: Boon Yew Low, Petaling Jaya (MY); Burton J. Carpenter, Austin, TX (US); Navas Khan Oratti Kalandar, Petaling Jaya (MY)

(21) Appl. No.: 13/924,627

(22) Filed: Jun. 24, 2013

(51) Int. Cl. H01L 23/495; H01L 21/56

(52) U.S. Cl. CPC H01L 23/49568; H01L 21/561
USPC 257/675; 438/122

(57) ABSTRACT

A semiconductor device includes a die pad and a semiconductor die having a mounting surface attached to the die pad and an opposite, active surface with die external terminals. The device has package external connectors, each having a bond region selectively electrically coupled to the die external terminals with a bond wire. A heat spreader has a first region that encloses an inner recessed region. A thermally conductive sheet is sandwiched between the inner recessed region of the heat spreader and the active surface of the die. At least the die, die external terminals, and the bond region are covered with an encapsulant.

### BACKGROUND OF THE INVENTION

The present invention relates to semiconductor device assembly or packaging and, more particularly, to a semiconductor device having a heat sink and a thermally conductive sheet disposed between the die and the heat sink.

Semiconductor devices or semiconductor die packages are known to generate heat during operation. The heat is generated by the semiconductor die, which often needs to be cooled to increase reliability and to enable higher operating speeds. Such cooling is often provided by a heat spreader, which is typically a metal sheet that is thermally coupled with the semiconductor die. During operation, heat is conducted away from the die and into the heat spreader, which can be convectively cooled by with a liquid, a fan, or simply by air convection.

Although fairly reliable and inexpensive to implement, such convection cooling as described above is not always adequate, especially for packages that consume relatively large currents. More specifically, an encapsulating compound with poor thermal conductive properties may be located between the semiconductor die and the heat spreader. Alternatively, the heat spreader may be directly attached to the semiconductor die with an epoxy or other adhesive that has poor thermal conductive properties. Furthermore, since accurate and consistent dispensing of the adhesive or epoxy is difficult to achieve, then excessive epoxy is often used, which is detrimental to the required thermal coupling between the semiconductor die and heat spreader.

Accordingly, it would be advantageous to provide a packaged die with improved thermal performance.

### BRIEF DESCRIPTION OF THE DRAWINGS

The invention, together with objects and advantages thereof, may best be understood by reference to the following description of preferred embodiments together with the accompanying drawings in which:

FIG. 1 is a cross-sectional side view of a conventional semiconductor die package;

FIG. 2 is a top plan view of a heat spreader in accordance with a preferred embodiment of the present invention;

FIG. 3 is a top plan view of a semiconductor device in accordance with a first preferred embodiment of the present invention;

FIG. 4 is a cross-sectional side view of the semiconductor device of FIG. 3 through 4-4′ in accordance with the first preferred embodiment of the present invention;

FIG. 5 is a cross-sectional side view of a semiconductor device in accordance with a second preferred embodiment of the present invention;

FIG. 6 is a top plan view of a heat spreader in accordance with another preferred embodiment of the present invention;

FIG. 7 is a top plan view of a semiconductor device in accordance with a third preferred embodiment of the present invention;

FIG. 8 is a cross-sectional side view of the semiconductor device of FIG. 7 through 8-8′ in accordance with the third preferred embodiment of the present invention;

FIG. 9 is a cross-sectional side view of a semiconductor device in accordance with a fourth preferred embodiment of the present invention;

FIG. 10 is a cross-sectional side view of a semiconductor device in accordance with a fifth preferred embodiment of the present invention;

FIG. 11 is a top plan view of a heat spreader in accordance with a further preferred embodiment of the present invention;

FIG. 12 is a top plan view of a semiconductor device in accordance with a sixth preferred embodiment of the present invention;

FIG. 13 is a cross-sectional side view of the semiconductor device of FIG. 12 through line 13-13′ in accordance with the sixth preferred embodiment of the present invention; and

FIG. 14 is a flow chart of a method for assembling a semiconductor device in accordance with a preferred embodiment of the present invention.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practised. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that module, circuit, device components, structures and method steps that comprises a list of elements or steps does not include only those elements but may include other elements or steps not expressly listed or inherent to such module, circuit, device components or steps. An element or step proceeded by “comprises . . . a” does not, without more constraints, preclude the existence of additional identical elements or steps that comprises the element or step.

In one embodiment, the present invention provides a semiconductor device including a die pad and a semiconductor die having a mounting surface and an opposite active surface with die external terminals. The mounting surface is attached to the die pad. The device has package external connectors each having a bond region selectively electrically coupled to the die external terminals by a bond wire. There is a heat spreader that has a first region that encloses an inner recessed region. A thermally conductive sheet is sandwiched between the inner recessed region and the die active surface. There is an encapsulating compound encapsulating at least the die external terminals and the bond region of each of the package external connectors.

In another embodiment, the present invention provides for a method for assembling a semiconductor device. The method includes attaching a semiconductor die to a die mount, the semiconductor die having an active surface with die external terminals; selectively electrically coupling package external connectors to the die external terminals with bond wires, wherein the bond wires are bonded to each of the package external connectors at a respective bond region thereof; sandwiching a thermally conductive sheet between the die active surface and a recessed region of a heat spreader, wherein the heat spreader has a first region enclosing the recessed region. The method also performs a process of encapsulating at least the die external terminals and the bond region of each of the package external connectors.

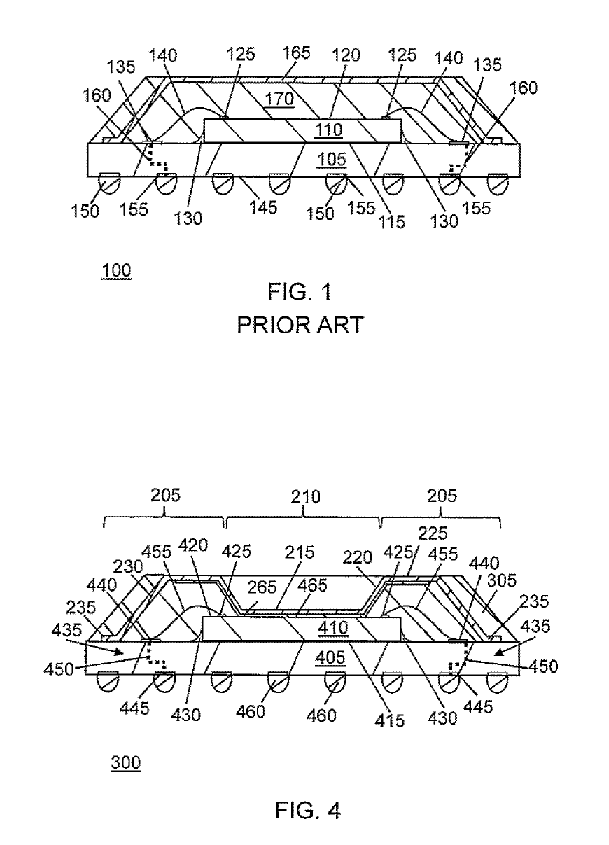

Referring now to FIG. 1, a cross-sectional side view of a conventional semiconductor device 100 is shown. The semiconductor device 100 includes a substrate 105 and a semiconductor die 110 with a mounting surface 115 and an opposite active surface 120. There are die external terminals 125 on the active surface 120. The die mounting surface 115 is attached to the substrate 105 with an epoxy 130. There are bond regions 135 on the substrate 105, and each bond region 135 is selectively electrically coupled to the die external terminals 125 by a bond wire 140. On an underside surface 145 of the substrate 105 are solder balls 150 mounted on external connector pads 155 that are electrically coupled to the bond regions 135 by vias or runners 160 or combinations of both. A heat spreader encloses the die 110 and bond wires 135, and an encapsulating compound 170 is located between the active surface 120 and the heat spreader 165. The encapsulating compound 170 has only marginal thermal conductive properties and thus the cooling of the semiconductor device 100 is relatively inefficient.

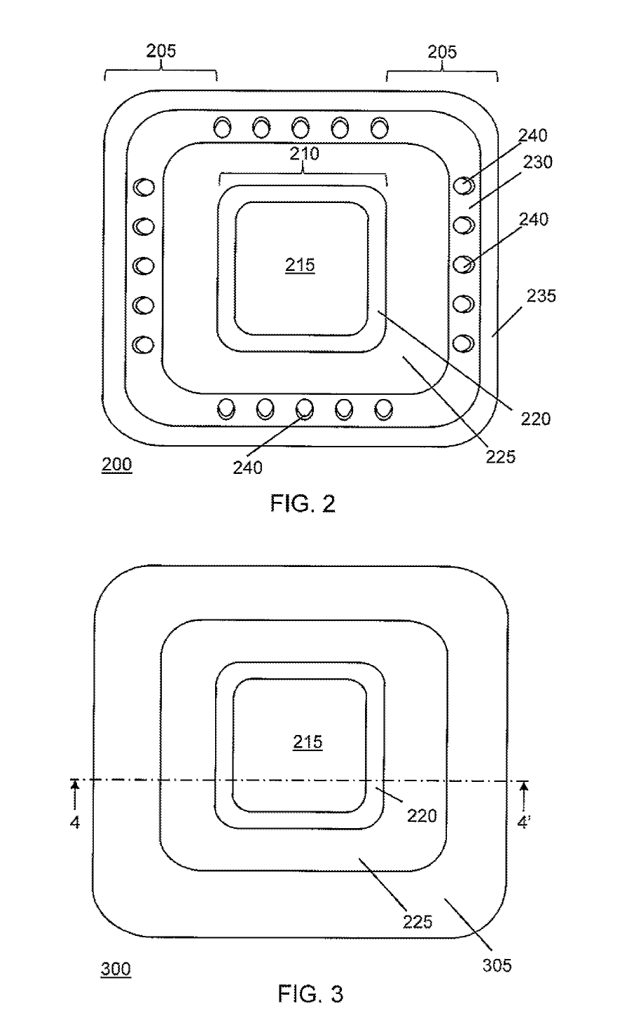

Referring to FIG. 2, a top plan view of a heat spreader 200 in accordance with a preferred embodiment of the present invention is shown. The heat spreader 200 may be made from a pressed sheet of copper or aluminium and includes a first region 205 enclosing an inner recessed region 210. The inner recessed region 210 includes a base 215 and walls 220. Also, the first region 205 includes an upper region 225 and an angled region 230, with apertures 240, and the extremities of the angled region 230 are formed into a flange 235.

FIG. 3 is a top plan view of a semiconductor device 300 in accordance with a first preferred embodiment of the present invention. The semiconductor device 300 includes the heat spreader 200 and an encapsulating compound 305 that is typically a transfer or press moulded compound as will be apparent to a person skilled in the art. In this embodiment the encapsulating compound 305 covers the angled region 230 and the flange 235.

FIG. 4 is a cross-sectional side view of the semiconductor device 300 through 4-4′ in accordance with the first preferred embodiment of the present invention. The semiconductor device 300 includes a die pad in the form of a package support substrate 405 and a semiconductor die 410 with a mounting surface 415 and an opposite active surface 420. There are die external terminals 425 on the active surface 420 that are input, output, ground or power supply nodes. The mounting surface 415 is attached to the package support substrate 405 with an epoxy 430. There are package external connectors 435 that are part of the package support substrate 405, and the package external connectors 435 each have a bond region 440 and external connector pads 445 respectively electrically coupled by vias, runners or combinations of runners and vias 450.

Each bond region 440 is selectively electrically coupled to the die external terminals 425 by a bond wire 455. Soldered to each one of the external connector pads 445 is an external connector solder deposit in the form of a solder ball 460 and thus each solder deposit or solder ball 460 is a ball of a ball grid array external connector arrangement. The solder balls 460 provide for mounting and electrically coupling the semiconductor device 300 to mounting pads of a circuit board.

A thermally conductive sheet 465 is sandwiched between the inner recessed region 210 and the active surface 420. The thermally conductive sheet 465 may be a graphite sheet, although other types of conductive sheets such as a Nano-carbon sheet or a carbon sheet can also be used. Also, the thermally conductive sheet 465 has an adhesive on one or both surfaces and is what is normally known as a single coated or double coated sheet. In this embodiment, the adhesive on one side of the thermally conductive sheet 465, attaches (bonds) the heat spreader 200 to the thermally conductive sheet 465. More specifically, the thermally conductive sheet 465 is attached (on an inner surface) to the inner recessed region 210 and the upper region 225. In another embodiment, the adhesive on one side of the thermally conductive sheet 465, attaches (bonds) the active surface 420 to the thermally conductive sheet 465. In yet a further embodiment, when the thermally conductive sheet 465 is double coated, the active surface 420 and the heat spreader 200 are attached (bonded) to the thermally conductive sheet 465. Also, the thermally conductive sheet 465 is attached on an inner surface to the inner recessed region 210 (base 215 and walls 220) and the upper region 225.

In this embodiment, the flange 235 is attached, by an epoxy (not shown), to the package support substrate 405 and the encapsulating compound 305 encapsulates the die external terminals 425, bond wires 455 and the bond region 440 of each of the package external connectors 435. Furthermore, the angled region 230 and a surface of the flange 235 are encapsulated by the encapsulating compound 305 and during moulding the apertures 305 allow the encapsulating compound 305 to pass through the angled region 230 in order to encapsulate the die external terminals 425, bond wires 455 and the bond regions 440. As shown, the outer surface of the base 215, walls 220 and upper region 225 provides part of an outer surface of the semiconductor device 200 which assists in heat dissipation.

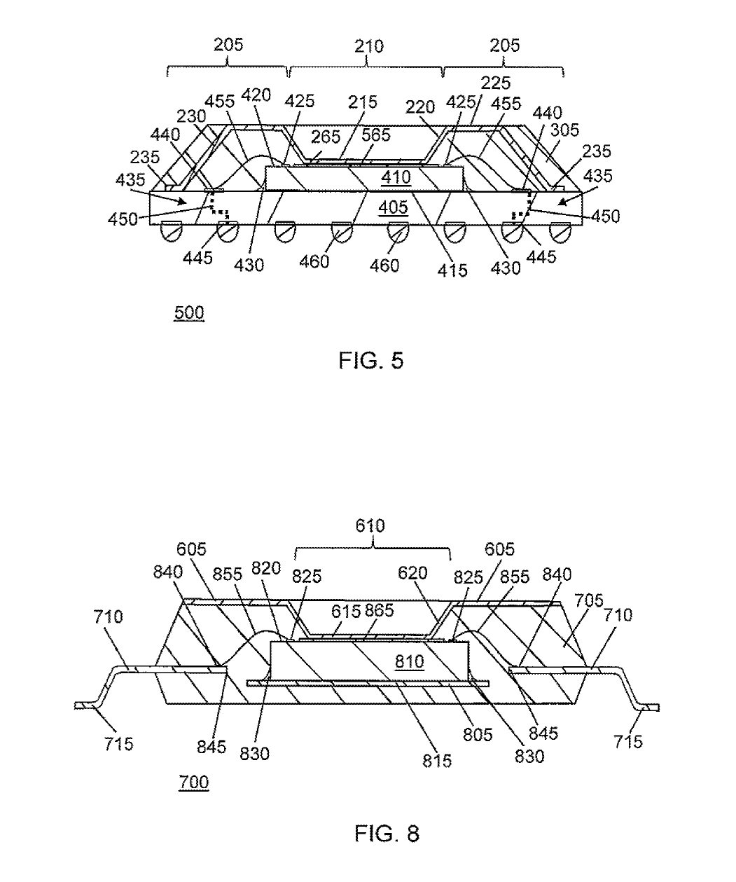

Referring to FIG. 5, a cross-sectional side view of a semiconductor device 500 in accordance with a second preferred embodiment of the present invention is shown. The semiconductor device 500 is similar to the die semiconductor package 300 and to avoid repetition only the differences will be described. In this embodiment the thermally conductive sheet 465 has been replaced by a smaller thermally conductive sheet 565 that again is a single coated or double coated graphite sheet, Nano-carbon sheet or carbon sheet. Also in this embodiment the thermally conductive sheet 565 is bonded by an adhesive coating to the active surface 420 and is only in direct contact with the recessed region 210 of the heat spreader 200. However, in another embodiment the thermally conductive sheet 565 is devoid of an adhesive coating and is simply sandwiched and lightly compressed between the active surface 240 and the recessed region 210.

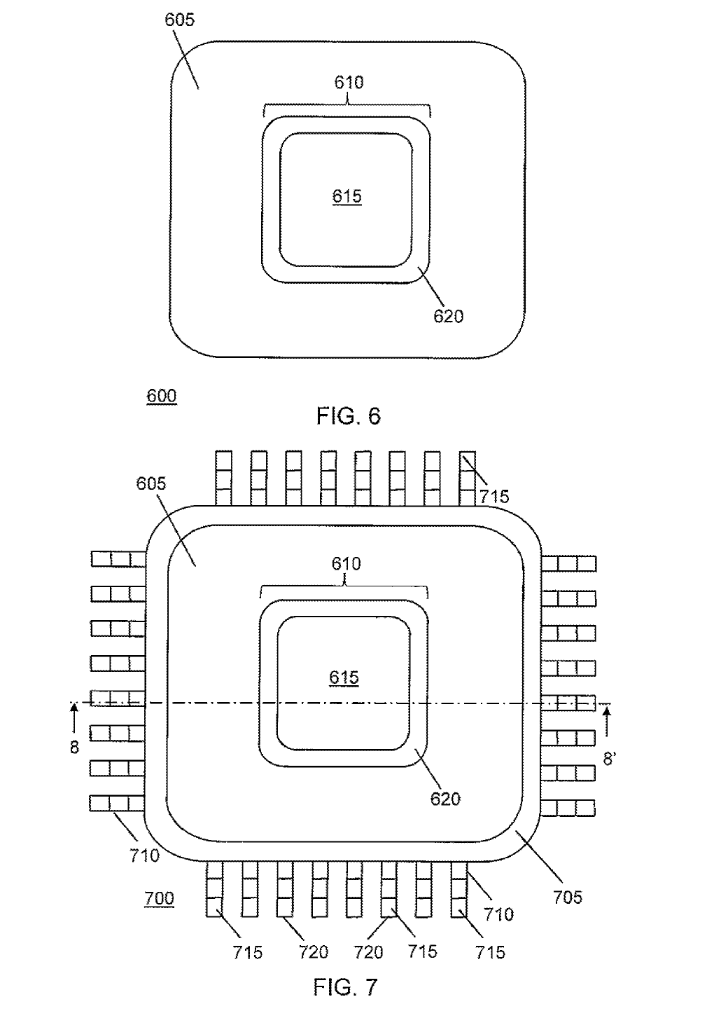

FIG. 6 is a top plan view of a heat spreader 600 in accordance with another preferred embodiment of the present invention. The heat spreader 600 is again typically made from a pressed sheet of copper or aluminium and includes a planar first region in the form of a frame 605 enclosing an inner recessed region 610 comprising a base 615 and walls 620.

FIG. is a top plan view of a semiconductor device 700 in accordance with a third preferred embodiment of the present invention. The semiconductor device 700 includes the heat spreader 600 and an encapsulating compound 705 that is typically a transfer or press moulded compound. In this embodiment package external connectors in the form of lead fingers 710 that protrude outwardly from the encapsulating compound 705 and the lead fingers 710 are bent to provide mounting feet 715 adjacent a free end 720 of the lead fingers 710. These mounting feet 715 provide for mounting and electrically coupling the semiconductor device 700 to mounting pads of a circuit board. It will therefore be apparent to a person skilled in the art that the semiconductor device 700 is a Quad Flat Package (QFP).

FIG. 8 is a cross-sectional side view of the semiconductor device 700 through 8-8′ in accordance with the third preferred embodiment of the present invention. The semiconductor device 700 includes a die pad in the form of a lead frame flag 805 and a semiconductor die 810 with a mounting surface 815 and an opposite active surface 820. There are die external terminals 825 on the active surface 820 that are input, output, ground or power supply nodes and the mounting surface 815 is attached to the lead frame flag 805 with an epoxy 830. There is a bond region 840 adjacent to an inner end 845 of each of the lead fingers 710 and each bond region 840 is selectively electrically coupled to the die external terminals 825 by a bond wire 855.

A thermally conductive sheet 865 is sandwiched between the inner recessed region 610 and the active surface 820. As above, the thermally conductive sheet 865 is a single coated or double coated sheet graphite sheet and other conductive sheets such as a Nano-carbon sheet or a carbon sheet can also be used. As shown, the thermally conductive sheet 865 is only in direct contact with the recessed region 610 of the heat spreader 600. However, the thermally conductive sheet 865 could be a larger sheet bonded to inner surface of the inner recessed region 210 (base 615 and walls 620) and the frame 605.

The encapsulating compound 705 encapsulates the die external terminals 825, bond wires 855 and the bond region 840 of each of the lead fingers 710. As shown, the outer surface of the base 615, walls 620 and frame 605 provides part of an outer surface of the semiconductor device 700, which assists in heat dissipation.

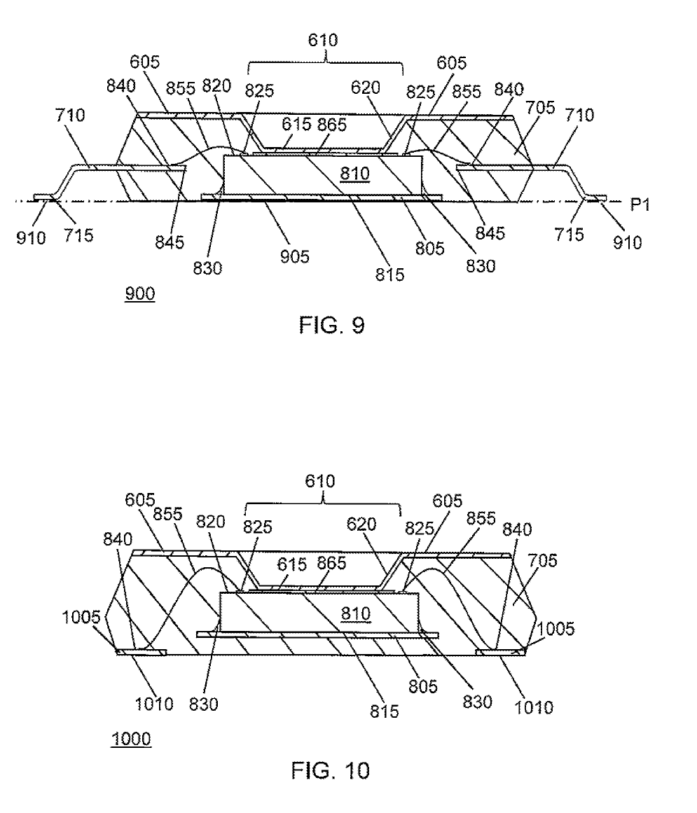

FIG. 9 is a cross-sectional side view of a semiconductor device 900 in accordance with a fourth preferred embodiment of the present invention. The semiconductor device 900 is similar to the die semiconductor package 700 and to avoid repetition only the differences will be described.

In this embodiment the lead frame flag 815 has been downset so that it provides an external surface 905 in the same seating plane P1 as underside mounting surfaces of the mounting feet 910. Thus, the lead frame flag 815 can provide, for example, additional thermal dissipation characteristics and electrical grounding connectivity for the semiconductor device 900.

FIG. is a cross-sectional side view of a semiconductor device 1000 in accordance with a fifth preferred embodiment of the present invention. The semiconductor device 1000 is similar to the die semiconductor package 700 and to avoid repetition only the differences will be described.

In this embodiment the lead fingers 710 have been shortened into pads 1005 and thus the semiconductor device 1000 is a Quad Flat No-lead (QFN) package. Furthermore, if required, the lead frame flag 815 can be sufficiently downset so that it provides an external surface in the same plane as external mounting surfaces 1010 of the pads 1005. From the above, it will be understood by a person skilled in the art that the flag 805, lead fingers 710 or pads 1005 are formed from a singulated lead frame, whereas the semiconductor die packages 300 and 500 are formed without a lead frame.

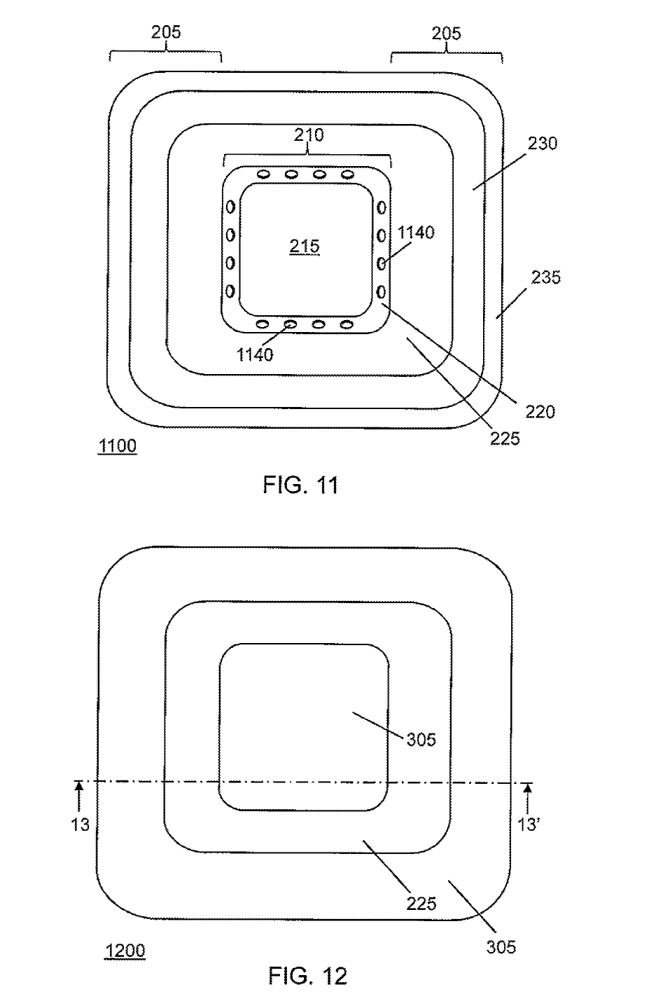

Referring to FIG. 11, a top plan view of a heat spreader 1100 in accordance with a further preferred embodiment of the present invention is shown. The heat spreader 1100 is similar to the heat spreader 200 and to avoid repetition only the differences will be described. In this embodiment the apertures 240 have been replaced with apertures 1140 in the walls 220 of the inner recessed region 210.

FIG. is a top plan view of a semiconductor device 1200 in accordance with a first preferred embodiment of the present invention. The semiconductor device 1200 is similar to the semiconductor device 300 and to avoid repetition only the differences will be described. In this embodiment the inner recessed region 210 has been filled with the encapsulating compound 305.

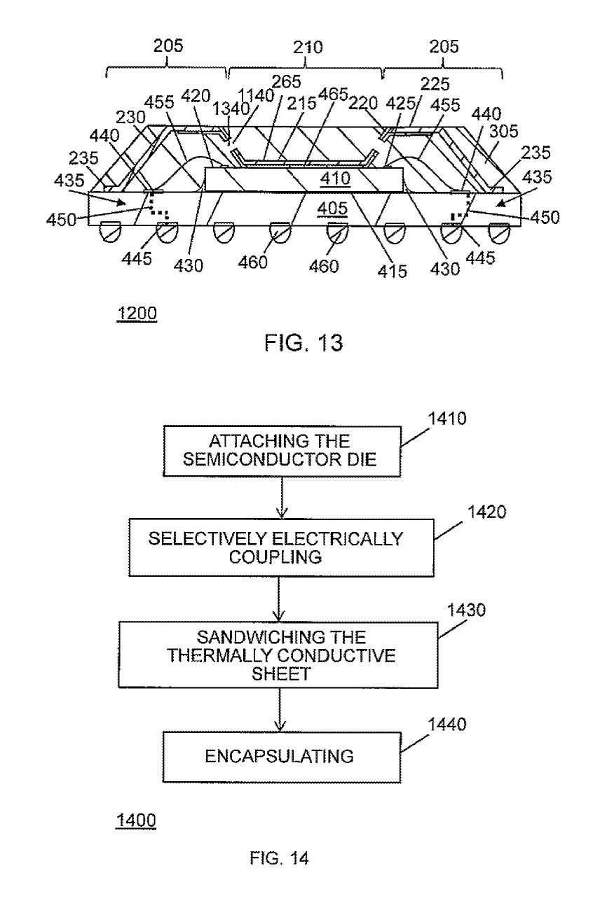

FIG. 13 is a cross-sectional side view of the semiconductor device 1200 through 13-13′ in accordance with the first preferred embodiment of the present invention. In this embodiment the thermally conductive sheet 465 has apertures 1340 aligned with the apertures 1140. During moulding of the encapsulating compound 305 the apertures 1140, 1340 allow the encapsulating compound 305 to pass through the walls 220 and sheet 465 in order to encapsulate the die external terminals 425, bond wires 455 and the bond regions 440.

FIG. 14 is a flow chart of a method 1400 for manufacturing a semiconductor device in accordance with a preferred embodiment of the present invention. By way of example only, the method 1400 will be described with particular reference to manufacturing the semiconductor device 300. However, it will be understood that the method 1400 is not limited to manufacturing this semiconductor device 300. The method 1400, at an attaching block 1410, performs attaching the semiconductor die 410 to a die pad such as the package support substrate 405. There is then performed, at a block 1420, a process of selectively electrically coupling package external connectors 435 to the die external terminals 425 by the bond wires 455 so that the bond wires 455 are bonded to each of the package external connectors 435 at their respective bond region 440. At a sandwiching block 1430, the thermally conductive sheet 565 is sandwiched between the active surface 420 and the recessed region 210 of a heat spreader 200. The method 1400 is completed at an encapsulating block 1440 which provides for encapsulating at least the die external terminals 425 and the bond region 440 of each of the package external connectors 435.

Advantageously, the present invention overcomes or at least alleviates at least one of the problems associated with thermally coupling a heat spreader to a semiconductor die. In this regard, the adhesive is either omitted from the conductive sheet. Alternatively, when the conductive sheet is single or double coated, the adhesive coating process ensures that a relatively thin and consistent coating is deposited on the conductive sheet. As a result, the adhesive coating does not substantially affect the thermal coupling of the heat spreader to a semiconductor die.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. For example the heat spreader may have cooling fins such as those often found on heat sinks and the like. It is understood, therefore, that this invention is not limited to the particular embodiment disclosed, but covers modifications within the spirit and scope of the present invention as defined by the appended claims.

1. A semiconductor device, including:
a die pad;
a semiconductor die having a mounting surface attached to the die pad and an opposite active surface with die external terminals;
package external connectors each having a bond region selectively electrically coupled to respective ones of the die external terminals with a bond wire;
a heat spreader having a first region enclosing an inner recessed region;
a thermally conductive sheet sandwiched between the inner recessed region and the die active surface; and
an encapsulating compound that covers at least the die external terminals and the bond regions of the package external connectors.

2. The semiconductor device of claim 1, wherein the thermally conductive sheet has an adhesive on at least one surface thereof.

3. The semiconductor device of claim 2, wherein the adhesive attaches the heat spreader to the thermally conductive sheet.

4. The semiconductor device of claim 2, wherein the adhesive attaches the thermally conductive sheet to the die active surface.

5. The semiconductor device of claim 1, wherein the inner recessed region and at least part of the first region of the heat spreader provide part of an outer surface of the semiconductor device.

6. The semiconductor device of claim 5, wherein the thermally conductive sheet is attached to the inner recessed region and at the least part of the first region.

7. The semiconductor device of claim 1, wherein the thermally conductive sheet is selected from a group consisting of a graphite sheet, a Nano-carbon sheet and a carbon sheet.

8. The semiconductor device of claim 1, wherein the die pad and package external connectors are part of a package substrate, and wherein the semiconductor device further comprises external connector pads electrically coupled to respective ones of said bond regions.

9. The semiconductor device of claim 8, further comprising an external connector solder deposit soldered to each of the external connector pads.

10. The semiconductor device of claim 9, wherein each external connector solder deposit comprises a solder ball of a ball grid array external connector arrangement.

11. The semiconductor device of claim 1, wherein the first region of the heat spreader has an angled region with a flange, wherein the flange is attached to the substrate.

12. The semiconductor device of claim 1, wherein the die pad and package external connectors are formed from a lead frame.

13. The semiconductor device of claim 12, wherein the package external connectors are leads fingers protruding from the encapsulating compound, the lead fingers having mounting feet at ends thereof.

14. The semiconductor device of claim 13, wherein the mounting feet each have a mounting surface in a seating plane and the die pad forms at least part an external surface of the package, wherein the external surface is in the seating plane.

15. A method of assembling a semiconductor device, comprising:
attaching a semiconductor die to a die pad, the semiconductor die having an active surface with die external terminals;
selectively electrically coupling package external connectors to the die external terminals with bond wires, wherein the bond wires are bonded to respective ones of the package external connectors at respective bond regions thereof;
sandwiching a thermally conductive sheet between the die active surface and an inner recessed region of a heat spreader, wherein the heat spreader has a first region enclosing the recessed region; and
encapsulating at least the die, the die external terminals, and the bond regions of the package external connectors with an encapsulant.

16. The method of claim 15, wherein the thermally conductive sheet has an adhesive on at least one surface thereof.

17. The method of claim 16, wherein the adhesive attaches the heat spreader to the thermally conductive sheet.

18. The method of claim 16, wherein the adhesive attaches the thermally conductive sheet to the die active surface.

19. The method of claim 15, wherein the inner recessed region and at least part of the first region of the heat spreader provide part of an outer surface of the semiconductor device.

20. The method of claim 15, wherein the thermally conductive sheet is selected from a group consisting of a graphite sheet, a Nano-carbon sheet and a carbon sheet.
